(19) United States
(12) Patent Application Publication
(10) Pub. No.: US 2023/0125151 A1
(43) Pub. Date: Apr. 27, 2023

(54) Bonding Wire and Method for Manufacturing the Same

(71) Applicant: Nippon Telegraph and Telephone Corporation, Tokyo (JP)

(72) Inventors: Toshiki Kishi, Tokyo (JP); Kota Shikama, Tokyo (JP)

(21) Appl. No.: 17/912,392

(22) PCT Filed: Apr. 7, 2020
(86) PCT No.: PCT/JP2020/015637

§ 371 Date: Sep. 16, 2022

(51) Int. Cl. H01L 23/00

(52) U.S. Cl. CPC H01L 24/48; H01L 24/45; H01L 24/85; H01L 24/43; H01L 2224/48135; H01L 2224/45026; H01L 2224/45015; H01L 2224/45014; H01L 2224/85007; H01L 2224/435

(57) ABSTRACT

A bonding wire includes a hollow member made of an insulator and mounted such as to bridge ICs formed with interconnects, such that a plurality of open ends is each closed by abutting on a surface of the interconnect that is a connection target, and a connection member made of a conductor, filling inside of the hollow member such as to bond to the surface of the interconnect at a location where the hollow member abuts on the surface of the interconnect.

### CROSS-REFERENCE TO RELATED APPLICATIONS

This patent application is a national phase filing under section 371 of PCT application no. PCT/JP2020/015637, filed on Apr. 7, 2020, which is incorporated herein by reference in its entirety.

### TECHNICAL FIELD

The present invention relates to a bonding wire used for electrical connection of ICs.

### BACKGROUND

With the significant growth of SNS (Social Networking Service) in recent years, the global communication traffic is increasing year by year. Further development of IoT (Internet of Things) and cloud computing techniques are expected to demand an even greater increase in traffic in future, and an expansion of communication capacities in and out of data centers is desired in order to support the vast amount of traffic.

Further size reduction and densification of boards and modules are therefore required, for which size reduction of electric ICs (Integrated Circuits) and optical ICs are necessary. For electrical connection between ICs, bonding wires are primarily used.

An IC is provided with an I/O (Input/Output) pad for electrical connection. While interconnects on an IC are several μm or less in width, an I/O pad is several 10s μm square, because of which the I/O throughput is limited as the IC becomes smaller. The smallest diameter of commercially available bonding wires is about 10 m when connecting a bonding wire to an interconnect on an IC, and therefore it was difficult to connect the bonding wire to the interconnect on the IC without using an I/O pad (see NPL 1).

### CITATION LIST

### Non Patent Literature

[NPL 1] “Bonding Capillaries—Catalogue—Japan”, SPT Japan Co., Ltd. revised in 2008, <http://www.smallprecisiontools.com/file/products/bonding/allcatalogues/Bonding %20Capillaries%20-%20Catalogue%20-%20Japan.pdf>.

### SUMMARY

### Technical Problem

Embodiments of the present invention were made to solve the above problem, with an object to provide a bonding wire that can be connected to an interconnect of an IC without an I/O pad.

### Means for Solving the Problem

A bonding wire according to embodiments of the present invention includes a hollow member made of an insulator and mounted such as to bridge ICs formed with an interconnect, such that a plurality of open ends is each closed by abutting on a surface of the interconnect that is a connection target, and a connection member made of a conductor, filling inside of the hollow member such as to bond to the surface of the interconnect at a location where the hollow member abuts on the surface of the interconnect.

A method of manufacturing a bonding wire according to embodiments of the present invention includes a first step of mounting a hollow member made of an insulator such as to bridge ICs formed with an interconnect, such that a plurality of open ends is each closed by abutting on a surface of the interconnect that is a connection target, a second step of injecting a connection member made of a conductor in a flowable state into the hollow member through an injection hole thereof such as to contact the surface of the interconnect at a location where the hollow member abuts on the surface of the interconnect, and a third step of hardening the connection member.

### Effects of Embodiments of the Invention

Embodiments of the present invention can provide a bonding wire with an ultra fine diameter of 10 μm or less, in which the bonding wire can be connected to an IC interconnect without using an I/O pad for connecting ICs.

### BRIEF DESCRIPTION OF THE DRAWINGS

FIG. 1 is a longitudinal cross-sectional view of a bonding wire according to a first embodiment of the present invention.

FIG. 2 is a flowchart explaining a manufacturing method of the bonding wire according to the first embodiment of the present invention.

FIG. 3 is an enlarged view of the bonding wire according to the first embodiment of the present invention near an air hole.

FIG. 4 is a longitudinal cross-sectional view of a bonding wire according to a second embodiment of the present invention.

FIG. 5 is a plan view of ICs and the bonding wire according to the first embodiment of the present invention.

FIG. 6 is a plan view of ICs and a bonding wire according to a third embodiment of the present invention.

FIG. 7 is a longitudinal cross-sectional view of a bonding wire according to a fourth embodiment of the present invention.

FIG. 8 is a plan view of ICs and the bonding wire according to the fourth embodiment of the present invention.

FIG. 9 is a plan view of another example of ICs and bonding wire according to the fourth embodiment of the present invention.

FIG. 10 is a plan view of ICs and a bonding wire according to a fifth embodiment of the present invention.

FIG. 11 is a plan view of another example of ICs and bonding wire according to the fifth embodiment of the present invention.

### DETAILED DESCRIPTION OF ILLUSTRATIVE EMBODIMENTS

### First Embodiment

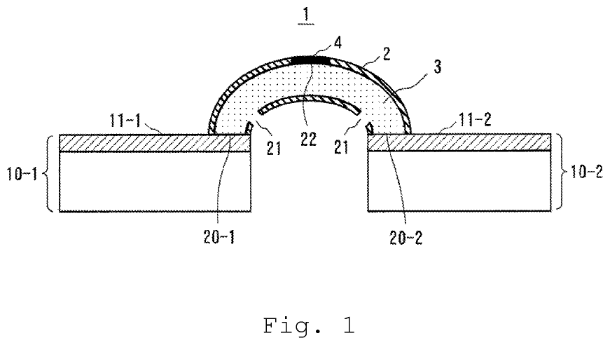

Hereinafter, embodiments of the present invention will be described with reference to the accompanying drawings. FIG. 1 is a longitudinal cross-sectional view of a bonding wire according to a first embodiment of the present invention. The bonding wire 1 of this embodiment includes a hollow member 2 made of an insulator and mounted such as to bridge ICs 10-1 and 10-2 formed with interconnects 11-1 and 11-2, such that a plurality of open ends 20-1 and 20-2 is each closed by abutting on a surface of the interconnect 11-1 or 11-2 that is a connection target and a connection member 3 made of a conductor, filling inside of the hollow member 2 such as to bond to the surface of the interconnect 11-1 or 11-2 at a location where the hollow member 2 abuts on the surface of the interconnect 11-1 or 11-2.

As long as interconnects 11-1 and 11-2 are formed on the surface for electrical connection, the ICs 10-1 and 10-2 maybe any integrated circuits, such as electric ICs formed with an electric circuit or optical ICs including an optical circuit and an electric circuit.

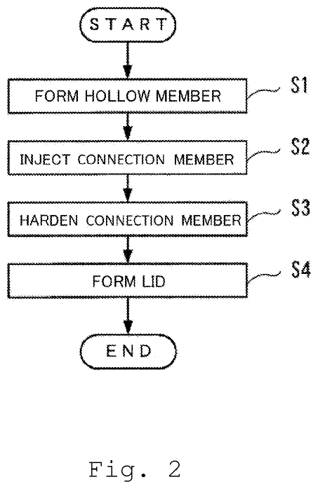

FIG. 2 is a flowchart explaining a manufacturing method of the bonding wire 1. First, the hollow member 2 is formed on the ICs 10-1 and 10-2 respectively having the interconnects 11-1 and 11-2 thereon (step S1 in FIG. 2).

The hollow member 2 has a capillary structure with an ultra fine diameter. In embodiments of the present invention in which the bonding wire 1 is connected to an interconnect on an IC, the hollow member 2 should preferably have an outside diameter of not more than several μm. Open ends 20-1 and 20-2 of the hollow member 2 are closed by abutting on the surface of the interconnects 11-1 and 11-2. The material of the hollow member 2 is an insulating resin, for example, such as epoxy resin, polyimide resin, and the like.

The hollow member 2 is provided with air holes 21 extending through from the outer wall to the inner wall for letting air inside the hollow member 2 escape during the filling with a connection member 3 and an injection hole 22 extending through from the outer wall to the inner wall for the filling with the connection member 3, these holes being formed during the process of mounting the hollow member 2 such as to bridge the ICs 10-1 and 10-2. FIG. 1 shows a finished form of the bonding wire 1, and therefore the injection hole 22 is closed with a resin lid 4 as will be described later.

One example of an apparatus that forms the hollow member 2 described above is a stereolithography 3D printer, which is an application of nano-level stereolithography using two-photon absorption. The nano-level stereolithography that uses two-photon absorption is disclosed in the following literature, for example: N. Lindenmann, G. Balthasar, D. Hillerkuss, R. Schmogrow, M. Jordan, J. Leuthold, W. Freude, and C. Koos1, “Photonic wire bonding: a novel concept for chipscale interconnects”, OPTICS EXPRESS, Vol. 20, No. 16, pp. 17667-17677, 2012.

Next, the connection member 3 in a flowable state is injected from the injection hole 22 that is not closed by the lid 4 yet into the hollow member 2 via a capillary or the like, for example (step S2 in FIG. 2). The air holes 21 have already been formed to the hollow member 2 by then, so that the air inside the hollow member 2 is let out of the hollow member 2 through the air holes 21 as the connection member 3 is injected. Accordingly, the connection member 3 moves inside the hollow member 2 and reaches the surface of the interconnects 11-1 and 11-2. At least one air hole 21 should preferably be provided at the locations above the interconnect 11-1 and above the interconnect 11-2, respectively, of the hollow member 2. This way, the connection member 3 can readily reach the surface of the interconnects 11-1 and 11-2.

One example of the connection member 3 in a flowable state is a conductive adhesive containing metal particle fillers such as silver particles or silver nanoparticles of about 0.5 μm in outside diameter dispersed in a paste-like binder, for example. Another example of the connection member 3 is molten metal having a low melting point, such as In, for example. In the case of using molten metal, it is necessary to select a metal having a lower melting point than that of the material of the hollow member 2 to prevent the resin hollow member 2 from melting. Indium has a melting point of about 156.6° C.

After injecting the connection member 3, the connection member 3 is hardened (step S3 in FIG. 2). In the case where a conductive adhesive is used as the connection member 3 in a flowable state, the conductive adhesive may be cured by applying heat. It goes without saying that the temperature of this heating should be set such as not to affect the hollow member 2 or the ICs 10-1 and 10-2. In the case where a molten metal is used as the connection member 3 in a flowable state, the molten metal may be cured by natural or forced cooling.

After hardening the connection member 3, the resin lid 4 is formed on the injection hole 22 of the hollow member 2 by a 3D printer so that the injection hole 22 is closed with the lid 4 (step S4 in FIG. 2). The reason for forming the lid 4 is to prevent impurities from entering the hollow member 2.

The formation of the bonding wire 1 illustrated in FIG. 1 is thus completed, whereby electrical connection is established between the interconnect 11-1 of the IC 10-1 and the interconnect 11-2 of the IC 10-2.

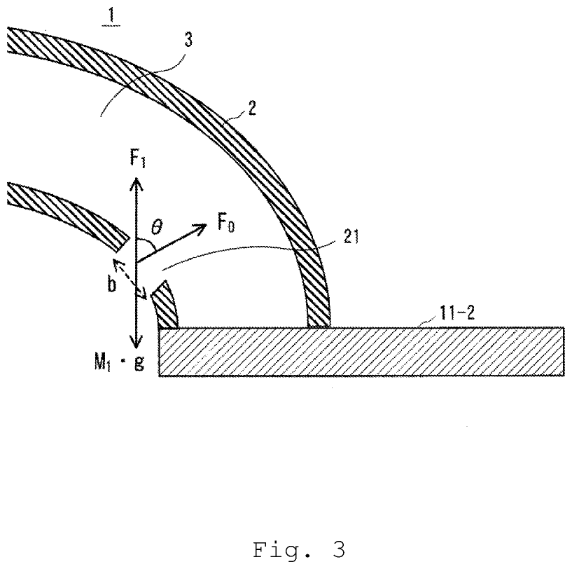

FIG. 3 is an enlarged view of the bonding wire 1 near the air hole 21. In the case of using a conductive adhesive as the connection member 3, there are the following relationships, where a [kg/m3] is the density of the conductive adhesive, γ [N/m] is the surface tension of the conductive adhesive, Fₒ [N] is a force of the surface tension as indicated in FIG. 3, F₁[N] is a force in the direction of cos θ of Fₒ, b[m] is the diameter of the air hole 21, M₁·g [N] is the gravity of the conductive adhesive leaking out of the air hole 21, and g [m/s²] is the gravitational acceleration.

### Equations (1)-(4)

$${F}_{0} = π \cdot b \cdot γ \qquad ( 1 )$$

$${F}_{1} = {F}_{0} \cdot cos θ \qquad ( 2 )$$

$${M}_{1} = \frac{4}{3} π \cdot {( \frac{b}{2} )}^{3} \cdot a \qquad ( 3 )$$

$${F}_{1} \geq {M}_{1} \cdot g \qquad ( 4 )$$

If the diameter b of the air hole 21 is set and the conductive adhesive is selected such that F, is greater than or equal to M₁·g, the conductive adhesive does not leak out of the air hole 21, so that the hollow member 2 can be filled with the conductive adhesive.

Similarly, when molten metal is used as the connection member 3, the diameter of the air hole 21 may be set and the molten metal may be selected such that the molten metal will not leak out of the air hole 21.

### Second Embodiment

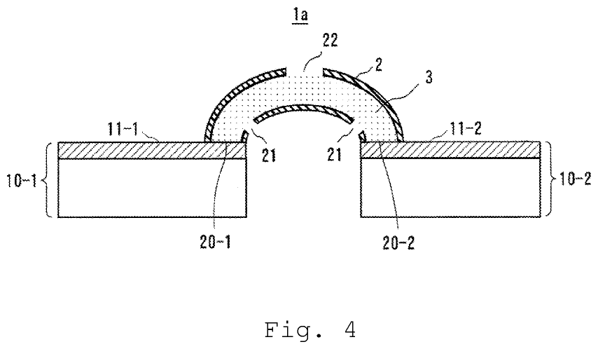

FIG. 4 is a longitudinal cross-sectional view of a bonding wire according to a second embodiment of the present invention. This embodiment shows an example of bonding wire 1a in which the lid 4 is not formed on the injection hole 22. In the case where the ICs 10-1 and 10-2 are mounted in a sealed module, the lid 4 is not necessary, as there is no possibility of impurities in the air entering the hollow member 2.

This embodiment can omit the production process of forming the lid 4 so that the process of manufacturing modules can be made simpler.

### Third Embodiment

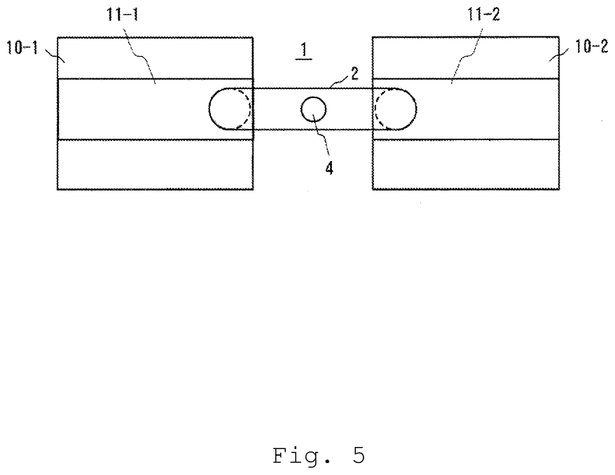

The first and second embodiments use a hollow member 2 having a ring-like cross-sectional shape as illustrated in the plan view of FIG. 5.

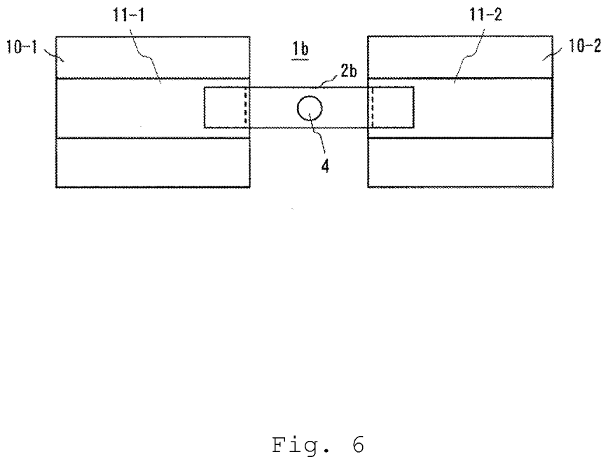

It is also possible to use a hollow member 2b having a square frame cross-sectional shape as in a bonding wire 1b of this embodiment illustrated in FIG. 6. The manufacturing method of the bonding wire 1b is similar to that of the first embodiment. As has been described in the second embodiment, the lid 4 need not necessarily be formed to the hollow member 2b.

### Fourth Embodiment

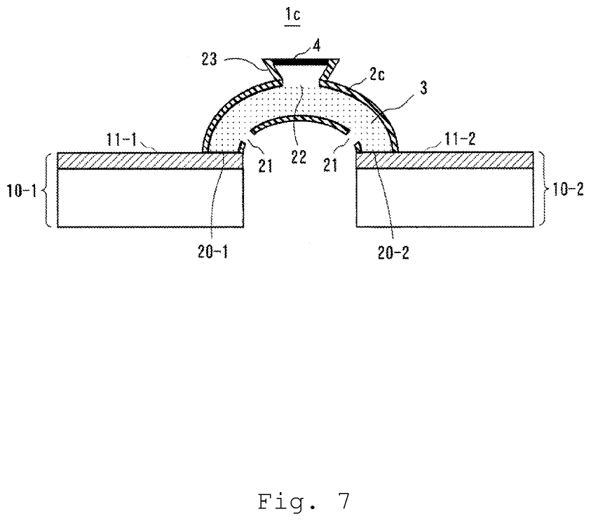

FIG. 7 is a longitudinal cross-sectional view of a bonding wire according to a fourth embodiment of the present invention. The hollow member 2c of the bonding wire 1c in this embodiment is provided with a funnel portion 23 that communicates with the injection hole 22 and gradually increases in diameter upward from the injection hole 22. With the funnel portion 23, the connection member 3 can be easily injected into the injection hole 22 from a capillary. The manufacturing method of the bonding wire 1c is similar to that of the first embodiment. The hollow member 2c with the funnel portion 23 can be formed by a 3D printer similarly to the first embodiment. The lid 4 need not necessarily be formed to the opening of the funnel portion 23.

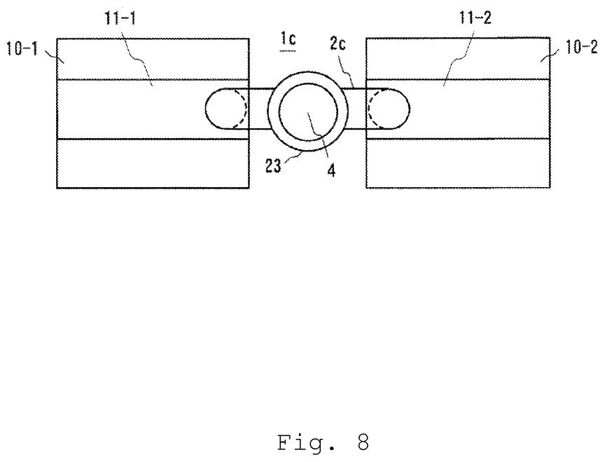

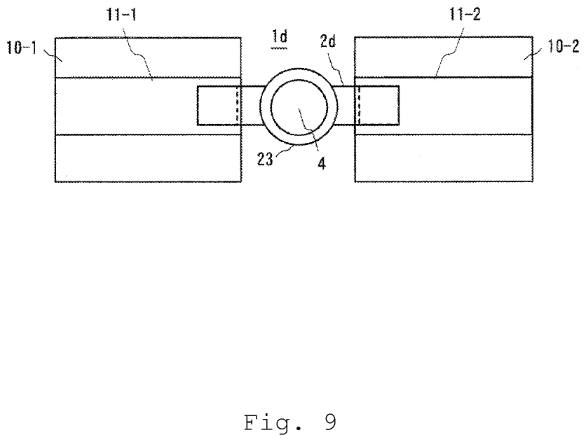

FIG. 8 is a plan view of the bonding wire 1c according to this embodiment. As illustrated in FIG. 8, this embodiment uses a hollow member 2c having a ring-like cross-sectional shape. It is also possible to use a hollow member 2d having a square frame cross-sectional shape as in a bonding wire 1d illustrated in FIG. 9.

### Fifth Embodiment

While the first to fourth embodiments show an example of connection between two points only, the hollow member of the bonding wire according to embodiments of the present invention can establish connection between not just two points but multiple points since the hollow member is fabricated using a 3D printer.

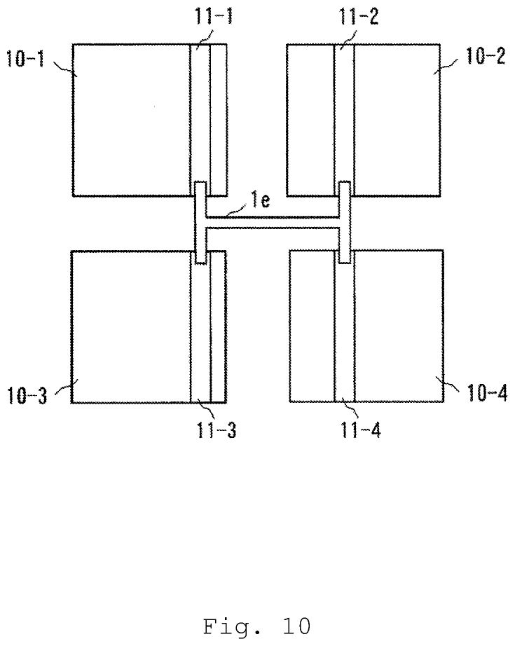

FIG. 10 is a plan view of a bonding wire according to a fifth embodiment of the present invention. FIG. 10 illustrates an example of bonding wire 1e that connects interconnects 11-1 to 11-4 of ICs 10-1 to 10-4 to each other. The example shown in FIG. 10 can establish connection between four points.

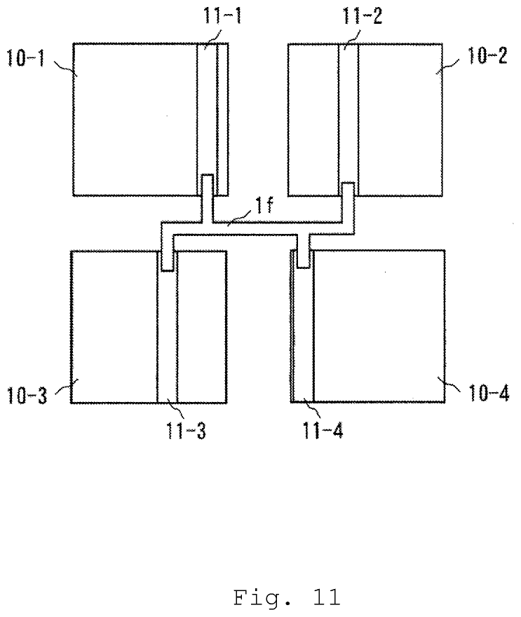

A bonding wire 1f of an even more complex shape as illustrated in FIG. 11 can be fabricated, too.

Compared to a conventional bonding wire that connects two points, this embodiment allows for a reduction in the number of wires, whereby short-circuiting between wires can be avoided. Also, a more complex connection becomes possible, as compared to conventional bonding wires.

### INDUSTRIAL APPLICABILITY

Embodiments of the present invention can be applied to a technique for connecting ICs.

### REFERENCE SIGNS LIST

1, 1a to 1f Bonding wire
2, 2b to 2d Hollow member
3 Connection member
4 Lid
10-1 to 10-4 IC
11-1 to 11-4 Interconnect
20-1, 20-2 Open end
21 Air hole
22 Injection hole
23 Funnel portion

1-8. (canceled)

9. A bonding wire comprising:
a hollow member comprising an insulator and mounted so as to bridge a plurality of integrated circuits each having an interconnect, wherein each of a plurality of open ends of the hollow member is closed by abutting on a surface of a respective interconnect; and
a connection member comprising a conductor, wherein the connection member fills an interior of the hollow member to bond to the surface of the respective interconnect at a location where the hollow member abuts on the surface of the respective interconnect.

10. The bonding wire according to claim 9, wherein the hollow member has a ring-like or square frame cross-sectional shape.

11. The bonding wire according to claim 9, wherein the hollow member comprises an air hole extending from an outer wall to an inner wall at a location above the respective interconnect.

12. The bonding wire according to claim 9, wherein the hollow member comprises an injection hole at an upper surface of the hollow member.

13. The bonding wire according to claim 12, further comprising a lid on the injection hole to close the injection hole.

14. The bonding wire according to claim 12, wherein the hollow member comprises a funnel portion communicating with the injection hole, wherein the funnel portion increases in diameter upward from the injection hole.

15. The bonding wire according to claim 14, further comprising a lid on an opening of the funnel portion to seal the injection hole.

16. A method of manufacturing a bonding wire, the method comprising:
mounting a hollow member comprising an insulator so as to bridge a plurality of integrated circuits each provided with an interconnect, wherein each of a plurality of open ends of the hollow member is closed by abutting on a surface of a respective interconnect;
injecting a connection member comprising a conductor in a flowable state into the hollow member through an injection hole to contact the surface of the respective interconnect at a location where the hollow member abuts on the surface of the respective interconnect; and
hardening the connection member.

17. The method according to claim 16, wherein the hollow member has a ring-like or square frame cross-sectional shape.

18. The method according to claim 16, further comprising forming the hollow member to include an air hole extending from an outer wall to an inner wall at a location above the respective interconnect.

19. The method according to claim 16, further comprising forming the hollow member to include a funnel portion communicating with the injection hole, wherein the funnel portion increases in diameter upward from the injection hole.

20. The method according to claim 19, further comprising forming a lid on the funnel portion to seal the injection hole with the lid.

21. The method according to claim 16, further comprising forming a lid on the injection hole to close the injection hole.

22. The method according to claim 16, wherein the hollow member is a product of a 3D printer.

23. A method of manufacturing a bonding wire, the method comprising:
forming a hollow member comprising an insulator, the hollow member comprising a first open end, a second open end, an injection hole, and an air hole extending from an outer wall to an inner wall;
mounting the hollow member to bridge a first integrated circuit provided with a first interconnect and a second integrated circuit provided with a second interconnect, wherein the first open end is closed by a first surface of the first interconnect and the second open end is closed by a second surface of the second interconnect; and
injecting a connection member comprising a conductor in a flowable state into the hollow member through the injection hole to contact the first surface of the first interconnect at the first open end of the hollow member and to contact the second surface of the second interconnect at the second open end of the hollow member.

24. The method according to claim 23, wherein the hollow member has a ring-like or square frame cross-sectional shape.

25. The method according to claim 23, wherein forming the hollow member comprises forming a funnel portion communicating with the injection hole, wherein the funnel portion increases in diameter upward from the injection hole.

26. The method according to claim 25, further comprising forming a lid on the funnel portion to seal the injection hole with the lid.

27. The method according to claim 23, further comprising forming a lid on the injection hole to close the injection hole after injecting the connection member.

28. The method according to claim 23, wherein forming the hollow member comprises forming the hollow member using a 3D printer.
